(19) United States
(12) Patent Application Publication
(10) Pub. No.: US 2007/0066098 A1
(43) Pub. Date: Mar. 22, 2007

(54) Printed circuit card connector

(75) Inventors: Patrick Liard, Vaux Sur Seine (FR); Yannick Bonneau, Pontoise (FR)

Correspondence Address: BIRCH STEWART KOLASCH & BIRCH, PO BOX 747, FALLS CHURCH, VA, 22040-0747, US

(73) Assignee: VALEO SYSTEMES DE CONTROLE MOTEUR, Osny (FR)

(21) Appl. No.: 10/563,607

(22) PCT Filed: Jul. 8, 2004
(86) PCT No.: PCT/FR04/01782

§ 371 Date: Jul. 10, 2006

(30) Foreign Application Priority Data
Jul. 9, 2003 (FR) 03/08388

(51) Int. Cl. H05K 1/00

(52) U.S. Cl. 439/79

(57) ABSTRACT

The invention relates to printed circuit card connector comprising a housing (2) having a first bearing portion (8) integral with the housing and rigidly connected to the housing so as to bear against a first face of the card, the connector including a second bearing portion (13) integral with the housing for bearing against a second face of the card, the second bearing portion bearing resiliently connected to the housing in such a manner as to enable the bearing portions to move relative to each other in a bearing direction, the bearing portions (8) being spaced apart at rest by a distance (d) that is less than the theoretical minimum thickness of the card.

### BACKGROUND OF THE INVENTION

Document U.S. Pat. No. 5,334,049 discloses a printed circuit card connector comprising a housing including a first portion for pressing against a first face of the card that is integral with the housing and rigidly connected thereto.

The connector includes a metal clip fitted on the housing and having one free end defining arms that are terminated by latches that form a second bearing portion for bearing against a second face of the card.

The bearing portions serve to position the connector on the printed circuit card while the connector is being soldered to the printed circuit card.

In order to guarantee that the connector is mounted without clearance on the card, the clip includes an elastically-deformable portion enabling the distance between the bearing portions to be varied, said bearing portions being spaced apart when at rest by a distance that is less than the theoretical minimum thickness of the printed circuit card.

Thus, putting the connector into place on the printed circuit card causes the bearing portions to move apart against a return force exerted by the deformed portion of the clip.

The effect of the return force is to press the first bearing portion firmly against the first face of the card, and because of the rigidity of the connection between the first bearing portion and the housing, this automatically guarantees that the connector is properly positioned relative to said face.

While held in this way, the connector and the card can be soldered together without any risk of the connector being poorly positioned relative to the card at the end of the soldering operation.

Nevertheless, using a clip requires not only that the clip itself be fabricated, but also an operation of assembling the clip to the housing, and that increases the cost of the connector. Furthermore, the presence of the clip makes it necessary to provide complex shapes on the housing that enable the clip to be received and held, while also leaving sufficient clearance to allow the deformable portion of the clip to deform.

Furthermore, manufacturing tolerances for the clip and assembly tolerances for assembling the clip on the housing lead to considerable variation in the spacing at rest between the bearing portions, which leads to wide dispersion in the force required for putting the connector into place on a card.

### OBJECT OF THE INVENTION

An object of the invention is to provide a connector enabling the dispersion in the force needed for putting the connector in place on a printed circuit card to be reduced.

### BRIEF SUMMARY OF THE INVENTION

According to the invention, there is provided a printed circuit card connector comprising a housing having a first bearing portion integral with the housing and rigidly connected to the housing so as to bear against a first face of the card, the connector being characterized in that it includes a second bearing portion integral with the housing for bearing against a second face of the card, the second bearing portion being resiliently connected to the housing in such a manner as to enable the bearing portions to move relative to each other in a bearing direction, the bearing portions being spaced apart at rest by a distance that is less than the theoretical minimum thickness of the card.

Thus, the housing and the bearing portions can be obtained in a single operation (e.g. by molding) in such a manner that the spacing between the bearing portions and the stiffness of the resilient connection are under much better control, thus making it possible to ensure that the force required for putting connectors of the invention into place on printed circuit cards is much more uniform.

In addition, any risk of losing or wrongly positioning the resilient bearing portion is eliminated.

### BRIEF DESCRIPTION OF THE DRAWING

The invention can be better understood in the light of the following description with reference to the figures of the accompanying drawing, in which:

FIG. 1 is a perspective view of a connector of the invention mounted on a printed circuit card;

FIG. 2 is an enlarged fragmentary section view seen looking along direction II in FIG. 1;

FIG. 3 is a side view of the FIG. 1 connector, with the connection pins omitted; and

FIG. 4 is a view analogous to FIG. 3, while the connector is not mounted on a printed circuit card.

### DETAILED DESCRIPTION OF THE INVENTION

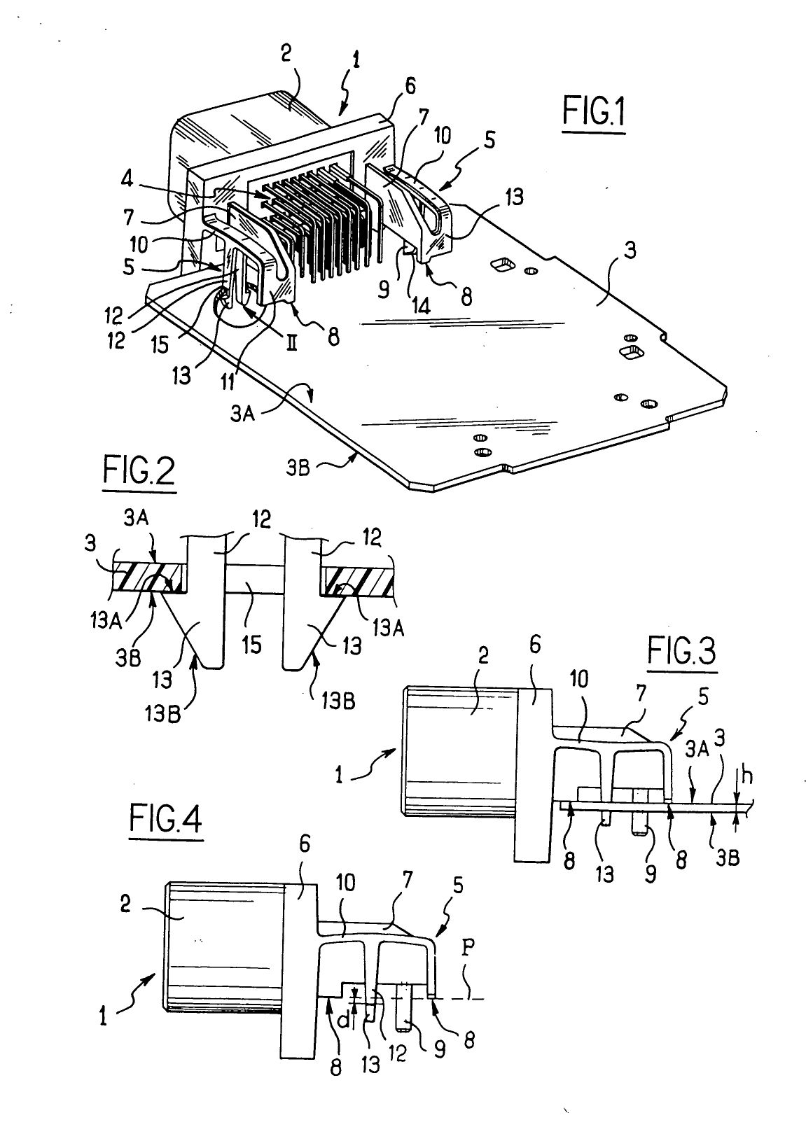

With reference to FIGS. 1, 2, and 3, the connector 1 of the invention comprises a housing 2 which in this case forms a female receptacle suitable for receiving a complementary male plug.

The connector 1 is fitted on a printed circuit card 3 and has a set of connection pins 4 for soldering to the card 3.

In order to ensure that the connector is held on the card 3 while soldering the connection pins 4, the housing 2 has two retention assemblies 5 made integrally with the housing 2 and projecting from a wall 6 of the housing that forms the end wall of the female receptacle. The retention assemblies 5 are symmetrical to each other in this example.

Each of the retention assemblies 5 comprises a partition 7 presenting two plane portions 8 facing towards the card 3. The plane portions 8 of the two partitions 7 define a bearing plane where the connector 1 bears against a face 3A of the card 3. The partitions 7 extend in a plane perpendicular to the bearing plane so that they present a high degree of stiffness in the bearing direction.

Each of the partitions 7 carries a positioning peg 9 which, when the connector is mounted on the card 3, extends through a matching orifice 14 in the card 3 located so as to position the connector 1 accurately on the card 3.

In the proximity of each partition 7, there extends a flexible blade 10 having an end portion 11 connected to the adjacent partition 7. Each flexible blade 10 carries substantially in its middle two arms 12 that are terminated by latches 13, the arms being integral with the housing 2 of the connector 1, e.g. being obtained by molding.

As shown in FIG. 4, at rest the faces 13A of the latches 13 that face towards the flexible blade 10 are spaced apart from the plane portions 8 by a distance d. This distance is less than the theoretical minimum thickness of the printed circuit card on which the connector is to be mounted, i.e. less than the nominal thickness of the card when diminished by the maximum manufacturing tolerance.

The connector is mounted on the card as follows, with the description making reference to FIGS. 1, 2, and 3.

The connector is presented to the card so that the positioning pegs 9 are in register with the matching orifices 14 in the card 3.

The connector is pressed against the card until the plane portions 9 come to bear against the facing face 3A of the card 3. The latches 13 are then engaged in passages 15 through the card 3, and the sloping outside edges 13B of the latches 13 bear against the edges of the passages 15 so as to bend the arms 12 and force them towards each other.

Nevertheless, given that the distance d is less than the thickness of the card 3, the latches 13 remain in part inside the passages 15.

In order to cause the latches 13 to pass right through the card 3, it is necessary to press on the flexible blade 10 over the arms 12 so as to bend the blade 10 until the top faces 13A of the latches 13 come level with the opposite face of the card 3. The flexibility of the arms 12 then automatically brings the top faces 13A of the latches 13 into a position where they face the opposite face 3B of the card 3 so as to lock the connector in the card 3.

Since the thickness of the card 3 is greater than the distance d, the top faces 13A of the latches 13 press against the opposite face 3B of the card 3 and prevent the flexible blade 10 from returning to its rest state. The blade thus remains flexed and thus exerts a return force tending to press the plane portions 8 against the card 3. This return force prevents any clearance existing between the card 3 and the plane portions 8, thereby guaranteeing that the connector 1 is properly positioned on the card 3.

In practice, the return force is sufficient to guarantee that the plane portions 8 press against the card 3 against the weight of the connector 1 or against the effect of any vibrations that might occur during soldering.

By obtaining the housing and the retention assemblies as a single piece, it is possible to control accurately not only the distance d between the bearing portions when at rest, but also the stiffness of the flexible blade 10, thus making it possible to reduce considerably the dispersion in the force needed for putting the connector of the invention in place on a card.

The invention is not limited to the particular features described above, but on the contrary covers any variant coming within the ambit of the invention as defined by the claims.

In particular, although the flexible blade is shown with an end portion connected to the adjacent partition 7, thus making it possible to control accurately the stiffness of the flexible blade and making the connector easier to mold, the flexible blade could have a free end that is independent of the partition. The flexible blade could then be terminated by a leg bearing against the card or it could merely be interrupted at the level of the arms 12 carrying the latches 13.

Although each of the flexible blades 10 is shown as carrying two arms 12, each of the flexible blades could carry only one arm 12, with the latch 13 of each arm extending in the opposite direction to the latch that terminates the arm carried by the other flexible blade.

Although the bearing portion that is resiliently connected to the housing is implemented in the form of latches carried at the ends of arms forming parts of a flexible blade extending on the same side of the card as the partition 7, thus enabling mounting to take place in a direction that is normal to the card, the bearing portion could be part of a flexible portion extending from the other side of the card. Under such circumstances, the support of the bearing portion does not pass through the card when the connector is mounted on the card. Mounting must then take place in a direction that is substantially parallel to the card.

Although the bearing portion of the connector that is rigidly connected to the housing is implemented by plane portions made on rigid partitions that are cantilevered out from the housing, the bearing portions could be of some other shape, such as a bearing plane or a bearing tripod.

Although the bearing members in this example are constituted by plane portions carried by the partitions or by the top faces of the latches, the bearing members could present any other shape enabling the connector to be pressed against the card, for example a point or a finger having a spherical end.

What is claimed is:

1. A printed circuit card connector comprising a housing (2) having a first bearing portion (8) integral with the housing and rigidly connected to the housing so as to bear against a first face of the card, the connector including a second bearing portion (13) integral with the housing for bearing against a second face of the card, the second bearing portion being resiliently connected to the housing in such a manner as to enable the bearing portions to move relative to each other in a bearing direction, the bearing portions (8) being spaced apart at rest by a distance (d) that is less than the theoretical minimum thickness of the card, the first bearing portion comprising at least one bearing member (8) defining a bearing plane of the connector and carried by a rigid partition (7) projecting from the housing (2) and extending perpendicularly to the bearing plane of the connector against the card, while the second bearing portion comprises at least one bearing member (13A) carried at the end of an arm (12) which is secured to a flexible blade (10) projecting from the housing (2) in such a manner that when the connector is mounted on the card, the flexible blade (10) extends beside the first face of the card and the arm (12) passes through the card, wherein the flexible blade (10) extends close to the rigid partition (7), the arm (12) being connected to the flexible blade (10) in a central zone thereof, the flexible blade having an end portion (11) which is connected to the adjacent rigid partition (7).

2. A connector according to claim 1, wherein the rigid partition (7) carries a positioning peg (9) for positioning the connector on the card.

3. A connector according to claim 1, wherein the connector has two retention assemblies (5) each comprising a rigid partition (7) and a flexible blade (10) connected to the rigid partition (7).

4. A connector to claim 3, wherein the retention assemblies (5) extend symmetrically relative to each other.
